(19) United States
(12) Patent Application Publication
(10) Pub. No.: US 2026/0090461 A1
(43) Pub. Date: Mar. 26, 2026

(54) SOCKET ASSEMBLIES FOR SEMICONDUCTOR DEVICE PACKAGES WITH EDGE FEATURES

(71) Applicant: Intel Corporation, Santa Clara, CA (US)

(72) Inventors: Wei LI, Chandler, AZ (US); Steven A. KLEIN, Chandler, AZ (US); Nicholas S. HAEHN, Scottsdale, AZ (US); Jacob SCHICHTEL, Chandler, AZ (US); Edvin CETEGEN, Chandler, AZ (US); Gang DUAN, Chandler, AZ (US)

(21) Appl. No.: 18/896,676

(22) Filed: Sep. 25, 2024

(51) Int. Cl. H01L 23/04; H01L 21/48; H01L 23/13; H01L 23/15; H01L 23/367; H01L 23/498

(52) U.S. Cl. CPC H10W 76/12; H10W 70/60; H10W 70/68; H10W 70/692; H10W 99/00; H10W 40/22

(57) ABSTRACT

Assemblies and methods of manufacturing assemblies that include sockets and packaged semiconductor chips are provided. The packages for the semiconductor chips can include cores that are formed from a solid amorphous glass layer.

### FIELD

Descriptions are generally related to semiconductor manufacturing, and more particular descriptions are related to assemblies comprising semiconductor chip packages and sockets.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, unwanted material interactions, precision and scaling requirements, power delivery requirements, limited failure tolerance, and material and manufacturing costs.

Semiconductor chips are typically “packaged” by attaching them to a package substrate. The package substrate can act as an interface between the semiconductor chip and other levels of interconnections, such as those for land grid array (LGA), pin grid array (PGA), or a reduced pin grid array (rPGA). A LGA, PGA, or rPGA can be used to mechanically attach and electrically couple one or more semiconductor chips to a circuit board, such as a mother board or logic board. A LGA comprises an array of lands (i.e., contacts) on a surface of a package and the array of lands can be mated to an array of pins on a socket which is mechanically attached to and electrically coupled to a circuit board. Similarly, for a PGA or a rPGA, an array of lands is mated to an array of contacts, and for a pin grid array, an array of pins on the package can be mated to an array of contacts in a socket. The rPGA has a reduced pitch between pins as compared to a PGA.

### BRIEF DESCRIPTION OF THE DRAWINGS

The figures are provided to aid in understanding the disclosure. The figures can include diagrams and illustrations of examples of structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the disclosure. Additionally, features are not necessarily illustrated relatively to scale due in part to the small sizes of some features and the desire for clarity of explanation in the figures.

FIG. 1A-1D provide semiconductor device assemblies that include packaged semiconductor devices and a socket.

FIG. 2 shows a view of an exemplary semiconductor package that is useful for a socket assembly.

FIGS. 3A-3C illustrate additional semiconductor device assemblies that include a packaged semiconductor device and a socket.

FIG. 4 shows a view of a semiconductor package that is useful for a socket assembly.

FIG. 5 shows an additional semiconductor device assembly that includes a packaged semiconductor device and a socket.

FIG. 6 provides an example of a computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, optically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine, as well as by physical operations. Physical operations can be performed by semiconductor processing and/or testing equipment, including computer systems that run testing protocols and/or operate aspects of semiconductor manufacturing equipment and systems. Although shown in a particular sequence or order, unless otherwise specified, the order of the actions can be modified. Thus, the illustrated diagrams should be understood as examples. The processes can be performed in a different order, and some actions can be performed in parallel. Additionally, one or more actions can be omitted and not all implementations may necessarily perform all actions.

Various components described can be a means for performing the operations or functions described. Components described can include software, hardware, or a combination of these. Some components can be implemented as software modules, hardware modules, special-purpose hardware (for example, application specific hardware, application specific integrated circuits (ASICs), and digital signal processors (DSPs)), embedded controllers, and/or hardwired circuitry. Other components can be semiconductor processing and/or testing equipment that is able to perform physical operations such as, for example, lithography, probing, material deposition (for example, chemical vapor deposition, atomic layer deposition, physical vapor deposition, electrodeposition, and/or sputtering), chemical mechanical polishing, etching, pick and place operations, and assembly operations.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, microelectronic chip, microelectronic die, semiconductor die, semiconductor device, and/or semiconductor chip are interchangeable and refer to a device comprising integrated circuits that can be formed in part from semiconductor materials.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip.

Interconnects in, for example, semiconductor chips that are integrated into heterogeneous packages (such as, for example, packages that include memory and logic chips), can also include through silicon vias (TSVs) that transverse the semiconductor chip device region. Semiconductor devices that have TSVs can blur distinctions between BEOL and FEOL processes.

Semiconductor chip interconnects can be created by forming a trench or though-layer via by etching a trench or via structure into a dielectric layer and filling the trench or via with metal. Dielectric layers can comprise, for example, low-κ dielectrics, SiO₂, silicon nitride (SiN), silicon carbide (SiC), and/or silicon carbonitride (SiCN). Low-κ dielectrics include for example, fluorine-doped SiO₂, carbon-doped SiO₂, porous SiO₂, porous carbon-doped SiO₂, combinations for the foregoing, and also these materials with gas-filled gaps or bubbles. Dielectric layers that include conductive features can be interlayer dielectric (ILD) features. In general, low-κ dielectrics exhibit a dielectric constant that is less than that of SiO₂.

The terms “package,” “packaging,” “IC package,” or “chip package,” “microelectronics package,” or “semiconductor chip package” are interchangeable and generally refer to an enclosed carrier of one or more chips, in which the chips are coupled to a package substrate and encapsulated. The package substrate provides electrical interconnections between the chip(s) and other chips and/or a motherboard or other circuit board for I/O (input/output) communication and power delivery. A package with multiple chips can, for example, be a system in a package.

A package substrate generally includes dielectric layers or structures having conductive structures on, through, and/or embedded in the dielectric layers. The dielectric layers can be, for example, build-up layers. Dielectric materials include Ajinomoto build-up film (ABF), although other dielectric materials are possible. Semiconductor package substrates can have cores or be coreless. Semiconductor package substrates having cores can have dielectric layers such as build-up layers on more than one side of a core, such as on two opposite sides of a core. Cores can include through-core vias that contain a conductive material. Other structures or devices are also possible within a package substrate.

A “core,” “substrate core,” or “package core” generally refers to a layer usually embedded within a package substrate. The core can provide structure or stiffness to a package substrate. A core is an optional feature of a package substrate. The core can be a dielectric organic or inorganic material and may have conductive vias extending through the layer. The conductive vias can include a metal, for example, copper. A package core can, for example, be comprised of a glass material (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy). In other examples, package substrate cores are one or more layers of a solid amorphous glass materials.

In further examples of a package substrate core, the substrate core is a glass core comprising one or more layers of a solid amorphous glass material. The glass substrate core can comprise a glass such as, for example, aluminosilicate, borosilicate, alumino-borosilicate, silica, and fused silica, that additionally optionally comprises one or more of the following: Al₂O₃, B₂O₃, MgO, CaO, SrO, BaO, SnO₂, Na₂O, K₂O, SrO, P₂O₃, ZrO₂, Li₂O, Ti, and/or Zn. In further examples of glass cores, the glass can comprise silicon and oxygen, as well as optionally any one or more of: aluminum, boron, magnesium, calcium, barium, tin, sodium, potassium, strontium, phosphorus, zirconium, lithium, titanium, and/or zinc. In some examples, a glass package substrate core comprises at least 23 % silicon, at least 26 % oxygen by weight. In further examples, the glass package substrate core comprises at least 23 % silicon, at least 26 % oxygen, and at least 5 % aluminum by weight.

Additionally, examples of solid amorphous glass substrate cores can be considered to have a rectangular prism volume. The rectangular prism volume can contain vias that have been filled with one or more different materials. A material in a via can be a conductive metal such as copper. Examples of solid amorphous glass substrate cores can have a thickness in the range of 50 μm to 1.4 mm. Additionally, the package substrate can include a multi-layer glass substrate. The package substrate in this example may be a coreless substrate. The multi-layer glass substrate can have a thickness, for example, in the range of 25 μm to 75 m. Further, glass substrate cores can have dimensions on a side of 5 mm to 600 mm. For example, the substrate core can be 5 mm by 5 mm up to 600 mm by 600 mm in two dimensions, but substrate cores do not necessarily have to have the same value in both dimensions.

A package substrate can include one or more interconnect bridges. The interconnect bridge can be partially, fully, or not embedded into the package substrate. An interconnect bridge provides interconnects between chips that are housed on the package substrate. The interconnects can provide signal I/O between the chips. Some interconnect bridges, such as ones that have conductive through-bridge vias, can also provide power to an operably connected chip. The interconnect bridge can include regions having traces that have a smaller width dimension (the smallest dimension of the trace), a smaller height dimension, and/or a length dimension than the vias and traces of the surrounding package substrate. For example, width dimensions (or smallest dimension) can be 3 μm or less and/or 10 μm or less in some regions. The interconnect bridges can also have smaller trace spacings than the surrounding package substrate. For example, trace center-to-center spacings can be 3 μm and/or less or 10 μm or less in some regions. The interconnect bridge substrate can comprise, for example, silicon, silicon-on-insulator, float glass, borosilicate glass, silicon dioxide, polymeric, one or more organic polymeric materials, ceramic, and/or a silicon nitride material. The interconnect bridge substrate can comprise, for example, one or more dielectric layers that are comprise of, silicon oxides, silicon nitride, silicon oxynitride, carbon-doped oxide, methyl silsesquioxane, hydrogen silsesquioxane, die backside film (DBF), an epoxy film, a B-stage epoxy film, other dielectric material. The interconnect bridge can also include a coreless substrate comprised of a plurality of dielectric layers. The dielectric layers can be, for example, die backside film (DBF), an epoxy film, a B-stage epoxy film, or other dielectric material. Other materials are also possible for interconnect bridge substrates. Other materials are possible.

For packages that include interconnect bridges, the pitch in the interconnect bridge region for first level interconnects (FLIs) assemblies can be less than the pitch for other regions of the FLI assembly. The pitch in the interconnect bridge region for FLIs can be, for example, less than or equal to 25 μm.

Incorporating through-bridge vias (TBVs) into interconnect bridges can enable power to be routed from a substrate package cavity to a semiconductor device attached to a package substrate. Through-bridge-vias can reduce the number of substrate routing layers required in a package substrate and can result in improved packaging yields. An interconnect bridge having TBVs can be for example, EMIB with TBVs, or EMIB-T. Depending on the bridge substrate material, a TBV may also be described as a through-silicon via (TSV) if the via traverses a region comprised of silicon, for example.

The package substrate manufacturing process is typically a build-up process that adds alternating layers of materials such as Cu and dielectric which are placed on a glass core through several thermal processes. These manufacturing processes place an enormous amount of tensile stress on a glass package substrate core, which can result in a normal stress at the edge of the panel and/or package substrate unit. The process of cutting a panel into individual package substrate units can result in fine cracks and defects along the glass substrate core edge. These cracks may be large enough to release the build up stress, resulting in package substrate failure due to core separation.

Further, during a manufacturing flow, glass-cored substrates can be handled by process equipment as many as hundreds of times. Glass can be a fragile material and can make the manufacturing process flows challenging. For example, when the glass core edge is contacted by a process tool or a LGA, PGA, or rPGA socket or other packaging assembly part, the contact increases the risk of chips and cracks that can propagate through the glass substrate core. A crack that propagates through a glass core, can cause the packaging substrate to for example, break, fracture, and/or warp so that it is no longer functional. Component losses during manufacturing can significantly increase the cost of manufacturing.

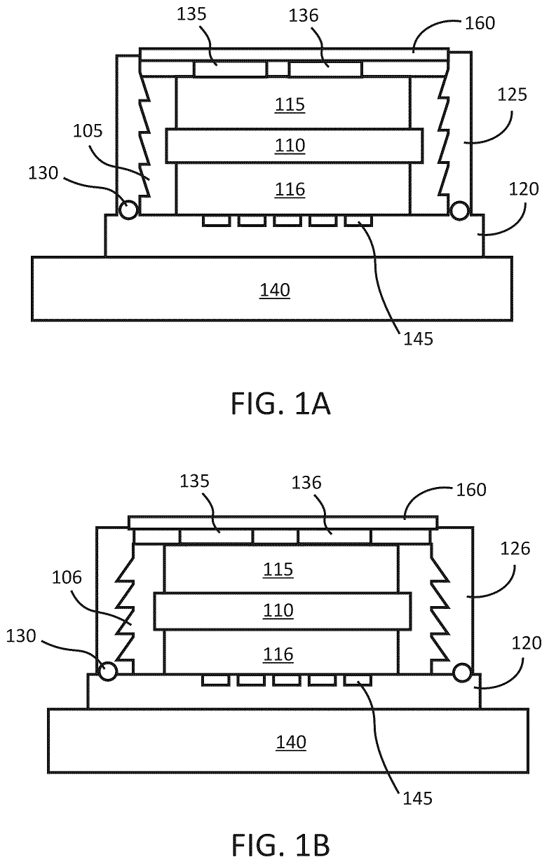

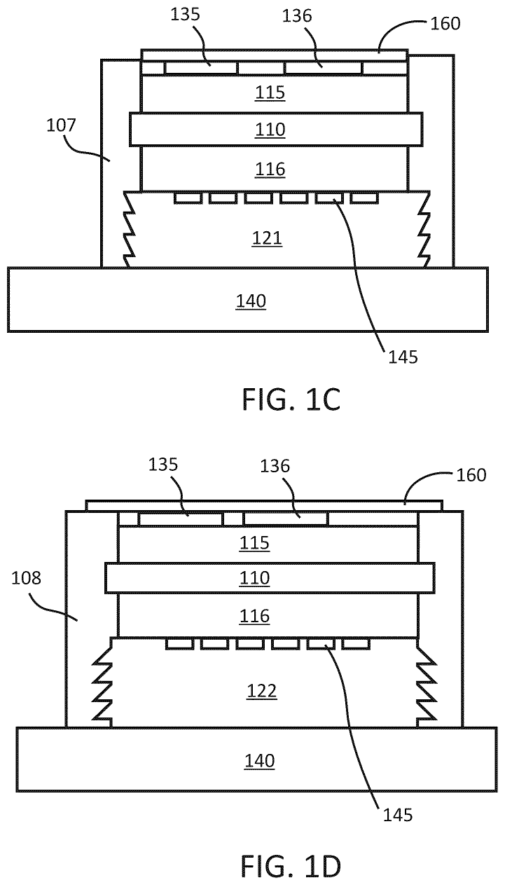

FIG. 1A-1D each illustrate a semiconductor device assembly comprising a semiconductor package and a socket. The view in FIG. 1 is a side-view in which the assembly has been sliced through along a plane so that the interior is visible. A semiconductor package includes a package substrate comprising a substrate core 110, and dielectric layers 115 and 116 (individual layers are not depicted for clarity), such as build-up layers as described herein. Dielectric layers 115 and 116 comprise conductive traces, conductive vias, and conductive pads (not shown). Conductive pads are between the semiconductor devices and the dielectric layers 115 and couple the semiconductor devices 135 and 136 electrically to the package substrate. The semiconductor package substrate can provide electrical power and I/O (input/output) interconnections to and/or between the semiconductor devices 135 and 136. Although two semiconductor devices 135 and 136 are shown, other numbers are possible, such as one, three, four, or more. The substrate core 110 can include conductive through-core vias (not shown). The package substrate also provides electrical power and I/O interconnections to the semiconductor devices 135 and 136 from the circuit board 140. Circuit board 140 can be, for example, a mother board, a logic board, a mainboard, a system board, and/or a printed circuit board. The package substrate can be electrically and communicatively coupled to the circuit board 140 through conductive features 145. Conductive features 145 can be pads, pins, rods, bumps, solder joins, or other types of interconnections. Additionally, the conductive features 145 can be features for a LGA, PGA, or rPGA socket, such as, for example conductive receptacles for pins (e.g., LGA), or pins that are inserted into a corresponding receptacle on the package substrate (e.g., PGA or a rPGA). The conductive features 145 can be comprised of a conductive material, such as a metal, layers of metals, or an alloy, such as, for example, copper, gold, aluminum, or solder.

A socket or other receptacle for the package substrate can comprise the conductive features 145 and bases 120 and 121. The socket bases 120 and 121 also have conductive regions (not shown) that can couple the circuit board 140 to the socket and the semiconductor package substrate. Conductive materials for conductive regions include metals, layers of conductive materials, and alloys, such as copper, gold, and/or aluminum. The heat spreader 160 is comprised of a thermally conductive material. The thermally conductive material can be, for example, a metal, layers of metals, or alloys of metals. The heat spreader 160 can be comprised of copper and/or aluminum, for example. The heat spreader 160 can be an integrated heat spreader (IHS).

In FIGS. 1A and 1B semiconductor package substrates also include edge regions 105 and 106 that have a side that includes an edge comprising peaks or teeth that are capable of locking to a corresponding edge of the walls 125 and 126 of the socket. The edges can also be considered serrated edges. Although four peaks on each side are shown, other numbers of peaks are also possible, such as 1-10 peaks or more. The socket can also include an optional hinge 130 which can allow the walls 125 and 126 to be moved away from the package so that the package can be removed from the socket.

FIGS. 1C and 1D show semiconductor package substrates that also include edge regions 107 and 108 that have a side that includes an edge comprising peaks or teeth that are capable of locking to a corresponding edge of the socket bases 122 and 122. The edges can also be serrated edges.

The edge regions 105, 106, 107 and 108 can be comprised of, for example, a polymeric material and/or a mold material. The polymeric material can be, for example, an epoxy material, an acrylic material, a urethane material, a polyimide material. The polymeric material can be one that is cured with a ultraviolet (UV) exposure process.

The package substrate core 110 can be comprised of any of the materials described herein for cores, such as organic or inorganic materials. The core 110 can be comprised of a glass material, and can be, for example, a solid glass core layer and/or material described herein.

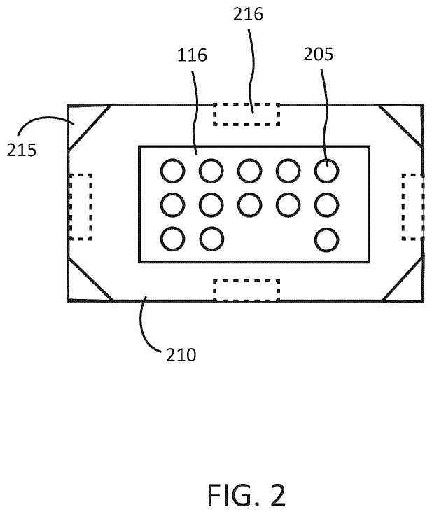

FIG. 2 illustrates a surface of the dielectric layers 116 of semiconductor packages of FIG. 1A-1D. The surface can be the one that comprises electrical contacts 205 that form conductive joins with corresponding conductive regions in a socket. Edge region 210 can be, for example, part of any of the edge regions 105, 106, 107, or 108 of FIG. 1A-1D. The locking feature regions 215 can be, for example, be the regions comprising peaks or teeth of FIG. 1A-1D of the edge regions 105, 106, 107, or 108. Alternatively, locking feature regions 216 can be located on sides of the edge region 210 (as shown by the dashed lines). An edge region 210 can comprise either the locking feature regions 215 or the locking feature regions 216.

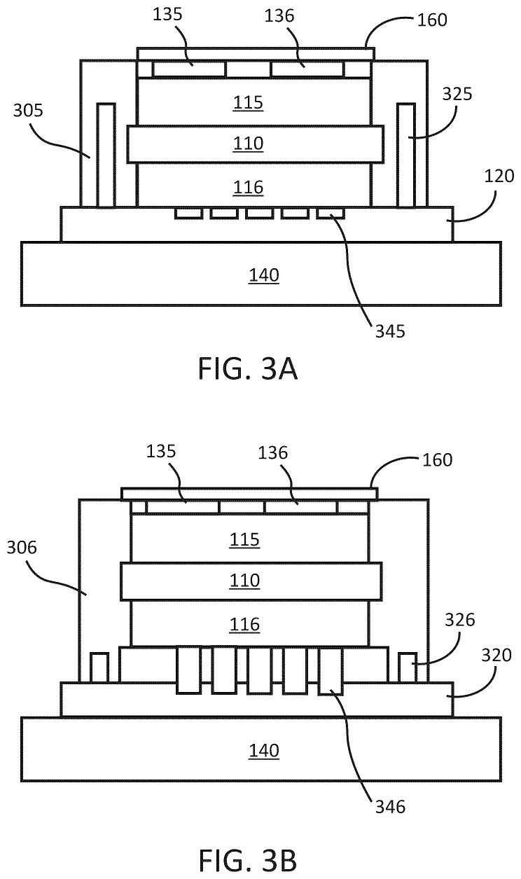

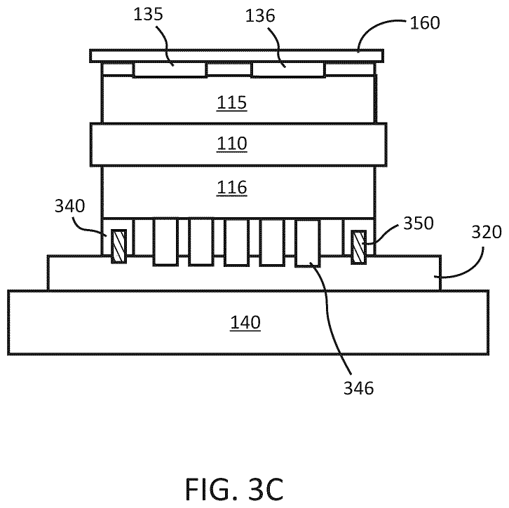

FIG. 3A-3C show additional assemblies comprising semiconductor devices 135 and 136, a package substrate, and a socket. The view in FIG. 3A-3C is a side-view in which the assembly has been sliced through along a plane so that the interior is visible. Where the numbering is the same for parts in FIG. 1A-1D as in FIG. 3A-3C, descriptions for parts for FIG. 1A-1D can be used for the same-numbered parts of FIG. 3A-3C. A semiconductor package includes a package substrate comprising a substrate core 110, and dielectric layers 115 and 116 (individual layers are not depicted for clarity), such as build-up layers as described herein. Dielectric layers 115 and 116 comprise conductive traces, conductive vias, and conductive pads (not shown). Conductive pads are between the semiconductor devices and the dielectric layers 115 and couple the semiconductor devices 135 and 136 electrically to the package substrate. The semiconductor package substrate can provide electrical power and I/O (input/output) interconnections to and/or between the semiconductor devices 135 and 136. Although two semiconductor devices 135 and 136 are shown, other numbers are possible, such as one, three, four, or more. The substrate core 110 can include conductive through-core vias (not shown). The package substrate also provides electrical power and I/O interconnections to the semiconductor devices 135 and 136 from the circuit board 140. Circuit board 140 can be, for example, a mother board, a logic board, a mainboard, a system board, and/or a printed circuit board. The package substrate can be electrically and communicatively coupled to the circuit board 140 through conductive joins 345 or 346. Conductive joins 345 and 346 can include pads, pins, rods, bumps, solder joins, press-fit pins and pin receptacles, or other types of interconnections. Additionally, the conductive joins 345 or 346 can be features for a LGA, PGA, or rPGA socket, such as, for example conductive receptacles for pins (e.g., LGA), or pins that are inserted into a corresponding receptacle on the package substrate (e.g., PGA or a rPGA). The conductive joins 345 and 346 can be multi-component joins and can be comprised of a conductive material, such as a metal, layers of metals, or an alloy, such as, for example, copper, gold, aluminum, and/or solder.

A socket or other receptacle for the package substrate can comprise part of the conductive joins 345 and 346 and bases 120 and 320. The socket bases 120 and 320 also have conductive regions (not shown) that can couple the circuit board 140 to the socket and the semiconductor package substrate. Conductive materials for conductive regions include metals, layers of conductive materials, and alloys, such as copper, gold, and/or aluminum. The heat spreader 160 is comprised of a thermally conductive material. The thermally conductive material can be, for example, a metal, layers of metals, or alloys of metals. The heat spreader 160 can be comprised of copper and/or aluminum, for example. The heat spreader 160 can be an integrated heat spreader (IHS).

In FIGS. 3A and 3B semiconductor package substrates also include edge regions 305 and 306 that have sides that include a cavity that is capable of receiving an alignment feature 325 or 326 of the socket. Alignment features 325 and 326 can extend through edge regions 305 and 306 various amounts and in some examples can completely traverse the height of the edge region 305 or 306 so that alignment feature 325 or 326 is exposed through the surface of edge region 305 or 306. A cavity can be a hole or a blind hole. The assembly of FIG. 3C includes an alignment region 340 on the package substrate and an alignment feature 350 that is part of the socket. The edge regions 305 and 306 and alignment region 340 can be comprised of, for example, a mold material, a polymer, or an epoxy material.

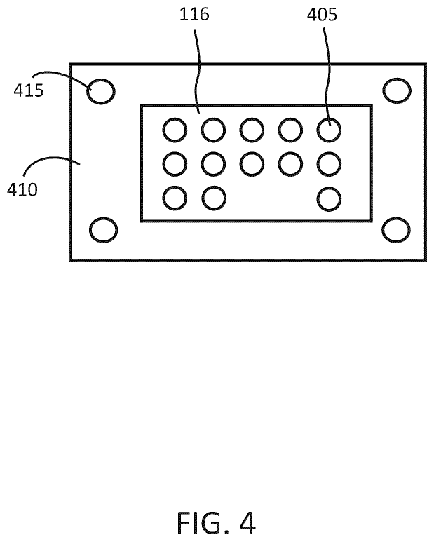

FIG. 4 illustrates a surface of dielectric layers 116 of the semiconductor packages of FIG. 3A-3B. The surface can be the one that comprises electrical contacts 405 that form conductive joins with corresponding conductive regions in a socket. Edge region 410 can be, for example, any of the edge regions 305 or 306 of FIG. 3A-3B. Edge region 410 include cavities 415 that are capable of receiving an alignment features, such as, for example, the alignment features 325 or 326 of a socket. Other numbers and/or shapes possible for cavities 415, such as 1-4 cavities 415 (4 are shown). Shapes include, circles, ovals, and rectangles and other multi-sided shapes. The cavities 415 can completely traverse a dimension of the edge region 410, or can partially traverse the edge region 410, i.e., the cavities can be blind holes or through-holes. Other locations are possible for cavities 415, such as, in one or more sides of the edge region 410, rather than in the corners.

Edge regions 305, 305, and/or 410 can comprise, for example, a polymeric material and/or a mold material. The polymeric material can be, for example, an epoxy material, an acrylic material, a urethane material, a polyimide material. The polymeric material can be one that is cured with a ultraviolet (UV) exposure process.

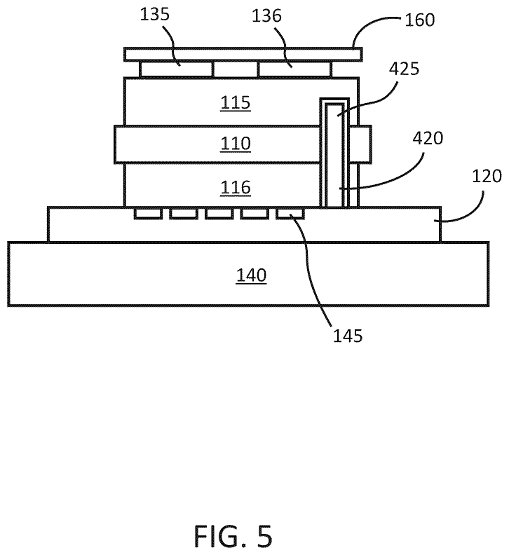

FIG. 5 provides an additional configuration for an assembly comprising packaged semiconductor devices and a socket. Where the numbering is the same for parts in FIG. 1A-1D as in FIG. 5, descriptions for parts for FIG. 1A-1D can be used for the same-numbered parts of FIG. 5. The semiconductor package substrate comprises a plated through hole (PTH) 420 which contains an alignment member 425. The PTH can be plated with a plastic, an epoxy, or a metal, for example. The PTH 420 can have different locations and/or lengths and can completely transverse the width of the package substrate. The alignment member 425 can be, for example, a rod or a press fit pin.

A semiconductor package substrate can be placed into a socket using, for example, a pick and place robotic arm, or a chip shooter that can be used for passive component placement and surface mount technology (SMT). A heat spreader can be mounted on the package substrate either before or after the package is placed into the socket. Retaining mechanisms (not shown), such as, for example, pins, screws, clamps, clips, lids, retention plates, or retention arms, can hold the semiconductor package in place in the socket allowing electrical connections to be maintained. The heat spreader can be mounted on the package using, for example, a pick and place robotic arm, or a chip shooter that can be used for passive component placement and SMT.

A method for making a package substrate having a through-hole for an alignment feature, such as, for example, the alignment member 425 can include creating through-holes during the process of singulating a panel on which packaging substrates have been manufactured. The panel can be cut into individual package substrates using a singulation system comprising, for example, polymer ablation modules that can remove package materials from between the package substrates and in the area of the through-hole leaving a package substrate core exposed. A singulation system can also comprise a laser, or a filamentation or Bessel beam process that singulates the package substrates or renders the core brittle so that it is subject to separation upon bending.

In general, circuit boards, such as circuit boards 140 can include a power supply that can control the amount of current and/or voltage going to components of the circuit board, such as the amount of current and/or voltage supplied to the semiconductor chips (such as semiconductor devices 135 and 136). Power can be supplied to packaged chips through-bridges that have TBVs. The circuit board can also provide interconnections processors and other computing devices and memory, such as DRAM.

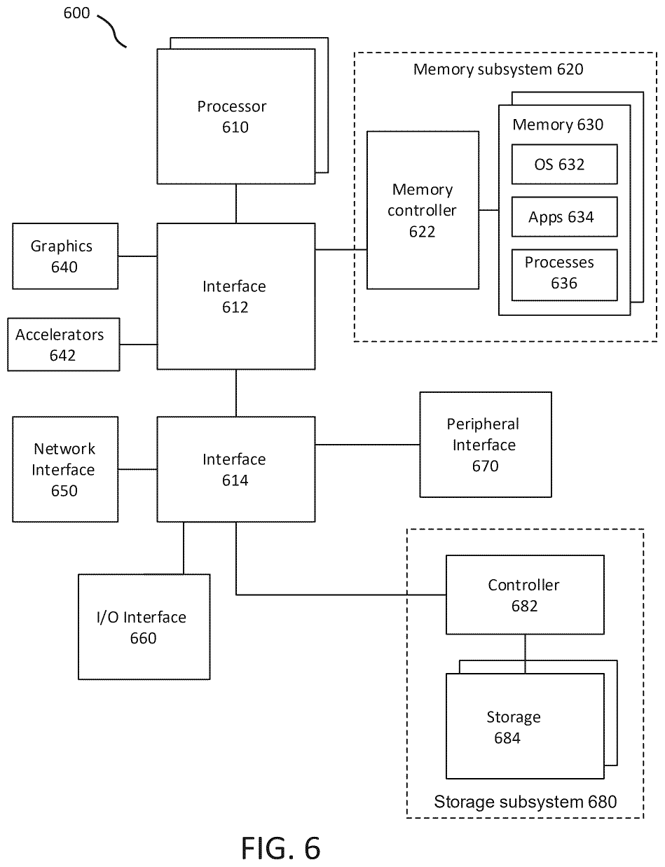

In FIG. 1A-1D, 3A-3C, and 5 the semiconductor devices (or chips) can be, for example, any combination of microprocessors, processors, CPUs (central processing units), GPUs (graphics processing units), processing cores, system on a chips, other processing hardware, a combination of processors or processing cores, programmable general-purpose or special-purpose microprocessors, accelerators, DSPs, I/O management, programmable controllers, ASICs, programmable logic devices (PLDs), HBM, and/or other memory devices. These semiconductor chip packages can be heterogeneous packages that incorporate different types of chips into one package. The semiconductor chips can be any of the chips, for example, described herein with respect to FIG. 6. The semiconductor chip packages described herein generally can be part of various larger package structures and configurations and the foregoing examples are not meant to limit the types of assemblies that are possible.

Additional materials for heat spreaders, such as the heat spreader 160 include, for example, a metallic plate comprised of, for example, a thermally conductive material, such as, copper, gold, palladium, aluminum, or a combination thereof. The heat spreader can be coupled to semiconductor devices through a thermal interface material (TIM). Typically, TIMs are deformable and thermally conductive materials, and a variety of materials are possible, such as, for example, pastes, gels, greases, epoxies, silicone-based materials, and adhesives. TIMS can comprise, metallic particles. Other materials are possible for TIMs.

FIG. 6 depicts an example computing system which can comprise circuit boards comprising assemblies as described herein. Additionally, instructions for operating assembly equipment for performing one or more aspects of the processes described herein can be stored and/or run on the computing system. A computing system 600 can include more, different, or fewer features than the ones described with respect to FIG. 6.

Computing system 600 includes processor 610, which provides processing, operation management, and execution of instructions for system 600. Processor 610 can include any type of microprocessor, CPU (central processing unit), GPU (graphics processing unit), processing core, or other processing hardware to provide processing for system 600, or a combination of processors or processing cores. Processor 610 controls the overall operation of system 600, and can be or include, one or more programmable general-purpose or special-purpose microprocessors, DSPs, programmable controllers, ASICs, programmable logic devices (PLDs), or the like, or a combination of such devices.

In one example, system 600 includes interface 612 coupled to processor 610, which can represent a higher speed interface or a high throughput interface for system components needing higher bandwidth connections, such as memory subsystem 620 or graphics interface components 640, and/or accelerators 642. Interface 612 represents an interface circuit, which can be a standalone component or integrated onto a processor die. Where present, graphics interface 640 interfaces to graphics components for providing a visual display to a user of system 600. In one example, the display can include a touchscreen display.

Accelerators 642 can be a fixed function or programmable offload engine that can be accessed or used by a processor 610. For example, an accelerator among accelerators 642 can provide data compression (DC) capability, cryptography services such as public key encryption (PKE), cipher, hash/authentication capabilities, decryption, or other capabilities or services. In some cases, accelerators 642 can be integrated into a CPU socket (e.g., a connector to a motherboard (or circuit board, printed circuit board, mainboard, system board, or logic board) that includes a CPU and provides an electrical interface with the CPU). For example, accelerators 642 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 642 can provide multiple neural networks, CPUs, processor cores, general purpose graphics processing units, or graphics processing units can be made available for use by artificial intelligence (AI) or machine learning (ML) models.

Memory subsystem 620 represents the main memory of system 600 and provides storage for code to be executed by processor 610, or data values to be used in executing a routine. Memory subsystem 620 can include one or more memory devices 630 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 630 stores and hosts, among other things, operating system (OS) 632 that provides a software platform for execution of instructions in system 600, and stores and hosts applications 634 and processes 636. In one example, memory subsystem 620 includes memory controller 622, which is a memory controller to generate and issue commands to memory 630. The memory controller 622 can be a physical part of processor 610 or a physical part of interface 612. For example, memory controller 622 can be an integrated memory controller, integrated onto a circuit within processor 610.

System 600 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 600 includes interface 614, which can be coupled to interface 612. In one example, interface 614 represents an interface circuit, which can include standalone components and integrated circuitry. In one example, user interface components or peripheral components, or both, couple to interface 614. Network interface 650 provides system 600 the ability to communicate with remote devices (e.g., servers or other computing devices) over one or more networks. Network interface 650 can include an Ethernet adapter, wireless interconnection components, cellular network interconnection components, USB, or other wired or wireless standards-based or proprietary interfaces. Network interface 650 can transmit data to a device that is in the same data center or rack or a remote device, which can include sending data stored in memory.

Some examples of network interface 650 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 600 includes one or more input/output (I/O) interface(s) 660. I/O interface 660 can include one or more interface components through which a user interacts with system 600 (e.g., audio, alphanumeric, tactile/touch, or other interfacing). Peripheral interface 670 can include additional types of hardware interfaces, such as, for example, interfaces to semiconductor fabrication equipment and/or electrostatic charge management devices.

In one example, system 600 includes storage subsystem 680. Storage subsystem 680 includes storage device(s) 684, which can be or include any conventional medium for storing data in a nonvolatile manner, such as one or more magnetic, solid state, and/or optical based disks. Storage 684 can be generically considered to be a “memory,” although memory 630 is typically the executing or operating memory to provide instructions to processor 610. Whereas storage 684 is nonvolatile, memory 630 can include volatile memory (e.g., the value or state of the data is indeterminate if power is interrupted to system 600). In one example, storage subsystem 680 includes controller 682 to interface with storage 684. In one example controller 682 is a physical part of interface 612 or processor 610 or can include circuits or logic in both processor 610 and interface 614.

A power source (not depicted) provides power to the components of system 600. More specifically, power source typically interfaces to one or multiple power supplies in system 600 to provide power to the components of system 600.

Examples of systems may be implemented in various types of computing, smart phones, tablets, personal computers, and networking equipment, such as switches, routers, racks, and blade servers such as those employed in a data center and/or server farm environment.

### EXAMPLES

An assembly can comprise: a socket wherein the socket comprises walls and the walls comprise first features capable of locking into corresponding second features; a package substrate wherein the package substrate is electrically coupled to the socket; a semiconductor chip wherein the semiconductor chip is electrically coupled to the package substrate; and an edge region on the package substrate comprising second features that are mated to first features to form a join. The socket can be a land grid array, a pin grid array, or a reduced pin grid array. The walls can comprise hinges that allow removal of the package substrate. The second features can be located on at least two corners of the edge region on the package substrate. The edge region can be comprised of a polymeric material. The package substrate can comprise a core and the core comprises a solid amorphous glass layer. The package substrate can comprise a core and the core comprises a solid amorphous glass layer that comprises aluminosilicate, borosilicate, alumino-borosilicate, silica, or fused silica. The assembly also can comprise a circuit board wherein the circuit board is electrically coupled to the socket. The assembly of claim 8 wherein the circuit board additionally comprises a power supply that is capable of controlling a voltage going to the semiconductor chip.

An assembly can comprise: a socket wherein the socket comprises an alignment member; a package substrate wherein the alignment member is in cavity that is in an edge region on an edge of the package substrate; a semiconductor chip wherein the semiconductor chip is electrically coupled to the package substrate; and a heat spreader wherein the heat spreader is coupled to a surface of the semiconductor chip. The edge region can be comprised of a polymeric material. The socket can be a land grid array, a pin grid array, or a reduced pin grid array. The package substrate can comprise a core wherein the core comprises a solid amorphous glass layer. The package substrate can comprise a core and the core comprises a solid amorphous glass layer that comprises aluminosilicate, borosilicate, alumino-borosilicate, silica, or fused silica. The solid amorphous glass layer can additionally comprise Al₂O₃, B₂O₃, MgO, CaO, SrO, BaO, SnO₂, Na₂O, K₂O, SrO, P₂O₃, ZrO₂, Li₂O, Ti, or Zn. The assembly can also comprise a circuit board wherein the circuit board is electrically coupled to the socket. The semiconductor chip can be a processor, a central processing unit, or a graphics processing unit.

A method of manufacturing an assembly can comprise: inserting a package substrate into a socket wherein the socket comprises an alignment member, wherein the package substrate comprises a cavity that traverses an edge region of the package substrate, and wherein the alignment member is inserted into the cavity; and placing a heat spreader on a surface of the package substrate. The alignment member can be a press-fit pin. The package substrate can comprise a core and the core comprises a solid amorphous glass layer.

Besides what is described herein, various modifications can be made to what is disclosed and implementations without departing from their scope. Therefore, the illustrations and examples herein should be construed in an illustrative, and not a restrictive sense.

What is claimed is:

1. An assembly comprising:
a socket wherein the socket comprises walls and the walls comprise first features capable of locking into corresponding second features;
a package substrate wherein the package substrate is electrically coupled to the socket;
a semiconductor chip wherein the semiconductor chip is electrically coupled to the package substrate; and
an edge region on the package substrate comprising second features that are mated to first features to form a join.

2. The assembly of claim 1, wherein the socket is a land grid array, a pin grid array, or a reduced pin grid array.

3. The assembly of claim 1 wherein the walls comprise hinges that allow removal of the package substrate.

4. The assembly of claim 1 wherein the second features are located on at least two corners of the edge region on the package substrate.

5. The assembly of claim 1 wherein the edge region is comprised of a polymeric material.

6. The assembly of claim 1 wherein the package substrate comprises a core and the core comprises a solid amorphous glass layer.

7. The assembly of claim 1 wherein the package substrate comprises a core and the core comprises a solid amorphous glass layer that comprises aluminosilicate, borosilicate, alumino-borosilicate, silica, or fused silica.

8. The assembly of claim 1 also comprising a circuit board wherein the circuit board is electrically coupled to the socket.

9. The assembly of claim 8 wherein the circuit board additionally comprises a power supply that is capable of controlling a voltage going to the semiconductor chip.

10. An assembly comprising:
a socket wherein the socket comprises an alignment member;
a package substrate wherein the alignment member is in cavity that is in an edge region on an edge of the package substrate;
a semiconductor chip wherein the semiconductor chip is electrically coupled to the package substrate; and
a heat spreader wherein the heat spreader is coupled to a surface of the semiconductor chip.

11. The assembly of claim 10 wherein the edge region is comprised of a polymeric material.

12. The assembly of claim 10 wherein the socket is a land grid array, a pin grid array, or a reduced pin grid array.

13. The assembly of claim 10 wherein the package substrate comprises a core and the core comprises a solid amorphous glass layer.

14. The assembly of claim 10 wherein the package substrate comprises a core and the core comprises a solid amorphous glass layer that comprises aluminosilicate, borosilicate, alumino-borosilicate, silica, or fused silica.

15. The assembly of claim 14 wherein the solid amorphous glass layer additionally comprises Al₂O₃, B₂O₃, MgO, CaO, SrO, BaO, SnO₂, Na₂O, K₂O, SrO, P₂O₃, ZrO₂, Li₂O, Ti, or Zn.

16. The assembly of claim 10 also comprising a circuit board wherein the circuit board is electrically coupled to the socket.

17. The assembly of claim 10 wherein the semiconductor chip is a processor, a central processing unit, or a graphics processing unit.

18. A method of manufacturing an assembly comprising:
inserting a package substrate into a socket wherein the socket comprises an alignment member, wherein the package substrate comprises a cavity that traverses an edge region of the package substrate, and wherein the alignment member is inserted into the cavity; and
placing a heat spreader on a surface of the package substrate.

19. The method of claim 18 wherein the alignment member is a press-fit pin.

20. The method of claim 18 wherein the package substrate comprises a core and the core comprises a solid amorphous glass layer.
